(19) United States
(12) Patent Application Publication
(10) Pub. No.: US 2022/0262738 A1
(43) Pub. Date: Aug. 18, 2022

(54) INTEGRATED CIRCUIT CHIP INCLUDING WIRING STRUCTURE

(71) Applicant: SAMSUNG ELECTRONICS CO., LTD., SUWON-SI (KR)

(72) Inventors: Jangeun LEE, Hwaseong-si (KR); Minjoo LEE, Seoul (KR); Wandon KIM, Seongnam-si (KR); Hyunbae LEE, Seoul (KR)

(21) Appl. No.: 17/475,506

(22) Filed: Sep. 15, 2021

(30) Foreign Application Priority Data
Feb. 15, 2021 (KR) 10-2021-0019686

(51) Int. Cl. H01L 23/532; H01L 23/522; H01L 23/528; H01L 21/768

(52) U.S. Cl. CPC H01L 23/53261; H01L 23/5226; H01L 23/53266; H01L 23/53295; H01L 23/5283; H01L 23/53238; H01L 21/7682; H01L 21/76846; H01L 21/76876; H01L 21/76804; H01L 21/76885

(57) ABSTRACT

An integrated circuit chip includes a base layer. A first wiring layer is disposed on the base layer and includes a plurality of first wiring structures. A second wiring layer is disposed on the first wiring layer and includes a plurality of second wiring structures. Each of the plurality of second wiring structures has a first metal layer and a second metal layer respectively having different resistivities. A third wiring layer is disposed on the second wiring layer and includes a plurality of third wiring structures. Each of the plurality of first wiring structures comprises Ru, Mo, W, or an alloy thereof. Each of the plurality of second wiring structures comprises Ru, Mo, W, or an alloy thereof. Each of the plurality of third wiring structures comprises a material different from a material of the plurality of first wiring structures.

### CROSS-REFERENCE TO THE RELATED APPLICATION

This application claims priority under 35 U.S.C. § 119 to Korean Patent Application No. 10-2021-0019686, filed on Feb. 15, 2021 in the Korean Intellectual Property Office, the disclosure of which is incorporated by reference in its entirety herein.

### TECHNICAL FIELD

The embodiments of the present inventive concept relate to an integrated circuit chip.

### DISCUSSION OF RELATED ART

The down-scaling of a semiconductor device has rapidly progressed as electronic devices have become increasingly miniaturized. Semiconductor devices are being designed to have a high integration level and low power consumption as a feature size of semiconductor devices is being steadily reduced.

To this end, down-scaling of a wiring structure applied to a semiconductor chip is progressing. For example, copper (Cu), cobalt (Co), etc. are used for a wiring structure applied to a semiconductor chip. Such a wiring structure may be formed through a damascene process.

### SUMMARY

Embodiments of the present inventive concept provide a wiring structure that exhibits low resistivity, provides a short electron mean free path and achieves a relatively easy patterning while having a thin line width, and an integrated circuit chip including the same.

According to an embodiment of the present inventive concept, an integrated circuit chip includes a base layer. A first wiring layer is disposed on the base layer and includes a plurality of first wiring structures. A second wiring layer is disposed on the first wiring layer and includes a plurality of second wiring structures. Each of the plurality of second wiring structures has a first metal layer and a second metal layer respectively having different resistivities. A third wiring layer is disposed on the second wiring layer and includes a plurality of third wiring structures. Each of the plurality of first wiring structures comprises Ru, Mo, W, or an alloy thereof. Each of the plurality of second wiring structures comprises Ru, Mo, W, or an alloy thereof. Each of the plurality of third wiring structures comprises a material different from a material of the plurality of first wiring structures.

According to an embodiment of the present inventive concept, an integrated circuit chip includes a first wiring layer comprising a plurality of first MoW alloy wiring structures, and a first encapsulation film surrounding each of the plurality of first MoW alloy wiring structures. A second wiring layer is disposed on the first wiring layer. The second wiring layer comprises a plurality of second MoW alloy wiring structures, and a second encapsulation film surrounding each of the plurality of second MoW alloy wiring structures. A portion of the plurality of second MoW alloy wiring structures is connected to a portion of the plurality of first MoW alloy wiring structures. A width of each of the plurality of first MoW alloy wiring structures and a width of each of the plurality of second MoW alloy wiring structures are in a range of about 12 nm or less.

According to an embodiment of the present inventive concept, an integrated circuit chip includes a substrate having an active surface, and a back surface opposite to the active surface. A front-end-of-line (FEOL) structure is disposed on the active surface of the substrate. The FEOL structure includes a transistor. A back-end-of-line (BEOL) structure is disposed on the FEOL structure. A plurality of bumps is disposed on the BEOL structure. The BEOL structure includes a first wiring layer comprising a plurality of first MoW alloy wiring structures. A second wiring layer is disposed on the first wiring layer. The second wiring layer comprises a plurality of second MoW alloy wiring structures. A third wiring layer is disposed on the second wiring layer. The third wiring layer comprises a plurality of third wiring structures each comprising a core metal, a liner film surrounding the core metal and a barrier film surrounding the liner film. A portion of the plurality of second MoW alloy wiring structures is connected to a portion of the plurality of first MoW alloy wiring structures. A portion of the plurality of first MoW alloy wiring structures is electrically connected to the transistor.

### BRIEF DESCRIPTION OF THE DRAWINGS

FIG. 1 is a cross-sectional view of an integrated circuit chip according to an embodiment of the present inventive concept.

FIG. 2 is a cross-sectional view showing a portion of the BEOL structure in FIG. 1.

FIGS. 3 to 22 are cross-sectional views of BEOL structure manufacturing procedures according to embodiments of the present inventive concept, respectively.

FIG. 23 is a cross-sectional view showing a portion of a BEOL structure according to an embodiment of the present inventive concept.

FIG. 24 is a cross-sectional view showing a portion of a BEOL structure according to an embodiment of the present inventive concept.

FIG. 25 is a cross-sectional view showing a portion of a BEOL structure according to an embodiment of the present inventive concept.

FIG. 26 is a cross-sectional view of a super-lattice structure of FIG. 25.

FIG. 27 is a cross-sectional view showing a portion of a BEOL structure according to an embodiment of the present inventive concept.

### DETAILED DESCRIPTION OF EMBODIMENTS

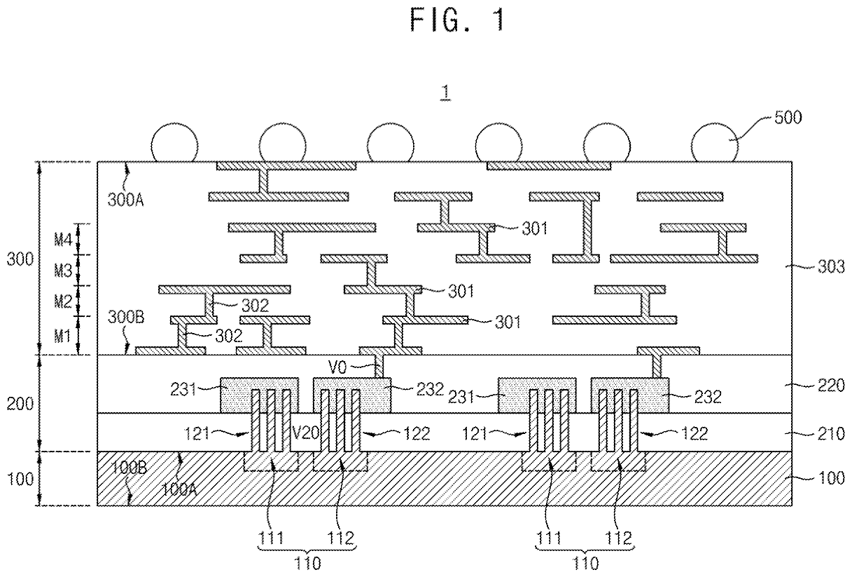

FIG. 1 is a cross-sectional view of an integrated circuit chip according to an embodiment of the present inventive concept.

Referring to FIG. 1, an integrated circuit chip 1 may include a power distribution network (PDN). The integrated circuit chip 1 may receive operating current and an operating voltage through the power distribution network. In an embodiment, the integrated circuit chip 1 may include an on-chip power distribution network (PDN) structure.

In an embodiment, the integrated circuit chip 1 may include a substrate 100 having an active surface 100A and a back surface 100B which are opposite surfaces (e.g., in a thickness direction of the substrate 100), a front-end-of-line (FEOL) structure 200 disposed on the active surface 100A of the substrate 100 (e.g., disposed directly thereon), a back-end-of-line (BEOL) structure 300 disposed on the FEOL structure 200 (e.g., disposed directly thereon), and bumps 500 disposed on the BEOL structure 300 (e.g., disposed directly thereon).

Here, the BEOL structure 300 may include the function of the power distribution network as described above.

In an embodiment, the integrated circuit chip 1 may include an integrated circuit. In some embodiments, the integrated circuit may be applied to a memory chip such as volatile memory (e.g., DRAM), non-volatile memory (e.g., ROM), flash memory, etc., an application processor chip such as a central processor (e.g., a CPU), a graphics processor (e.g., a GPU), a digital signal processor, a crypto-processor, a microprocessor, a microcontroller, etc., and a logic chip such as analog-to-digital converter, an application-specific integrated circuit (ASIC), etc., and may also be applied to a power management chip such as a power management integrated circuit (PMIC). However, embodiments of the present inventive concept are not limited thereto.

In an embodiment, the substrate 100 may include at least one semiconductor material. For example, the semiconductor material may be at least one compound selected from Si, Ge, SiGe, GaP, GaAs, SiC, SiGeC and InP. However, embodiments of the present inventive concept are not limited thereto. In some embodiments, the substrate 100 may be a hulk substrate (e.g., a bulk silicon substrate) or a semiconductor-on-insulator (SOI) substrate.

The substrate 100 may include a channel region 110 protruding upwards from the active surface 100A. For example, the channel region 110 may protrude from the substrate 100 in a vertical direction perpendicular to the active surface 100A. Here, the vertical direction means a thickness direction of the integrated circuit chip 1.

The FEOL structure 200 may be disposed on the active surface 100A of the substrate 100. For example, in an embodiment a lower surface of the FEOL structure 200 may directly contact an upper surface of the active surface 100A. In an embodiment, the FEOL structure 200 may be formed through an FEOL process. The FEOL process may refer to a process for forming individual elements, such as a transistor, a capacitor, a resistor, etc., on a substrate in a manufacturing procedure for the integrated circuit chip 1. For example, the FEOL process may include planarizing and cleaning a wafer, forming a trench, forming a well, forming a gate line, forming a source and a drain, etc. However, embodiments of the present inventive concept are not limited thereto.

In an embodiment, the FEOL structure 200 may constitute a logic cell including a fin field effect transistor (FinFET). However, embodiments of the present inventive concept are not limited thereto and the FEOL structure 200 may be various different structures. In an embodiment, the FEOL structure 200 may constitute a logic cell including a multi-bridge channel field effect transistor (MBCFET), a gate all around field effect transistor (GAAFET), a metal-oxide-semiconductor field effect transistor, a system large scale integration (LSI), a microelectromechanical system (MEMS), an active device, or a passive device which includes a plurality of transistors. Also, the transistor according to an embodiment of the present inventive concept may be a three-dimensional field effect transistor (e.g., VFET) having a gate all around structure.

In some embodiments, the integrated circuit chip 1 may further include a lower insulating film 210 disposed on the active surface 100A of the substrate 100. For example, as shown in FIG. 1, the lower insulating film 210 may be disposed directly on the active surface 100A of the substrate 100. In an embodiment, the lower insulating film 210 may extend to have a predetermined thickness on opposite side surfaces of the channel region 110 and the active surface 100A of the substrate 100. The lower insulating film 210 may be disposed only at lower portions of the opposite side surfaces of the channel region 110. The lower insulating film 210 may include an insulating material. For example, in an embodiment, the lower insulating film 210 may include at least one compound selected from silicon oxide, silicon nitride and silicon oxynitride. However, embodiments of the present inventive concept are not limited thereto.

The protrusion height of the channel region 110 may be greater than the thickness of the lower insulating film 210. For example, the channel region 110 may have a shape protruding from the lower insulating film 210 in the vertical direction and extending through the lower insulating film 210.

In an embodiment, the channel region 110 may include, for example, a well doped with a dopant or a conductive region doped with a dopant. For example, the conductive region may include a first doped region 111 and a second doped region 112. In an embodiment, the first doped region 111 may be an n-type doped region, whereas the second doped region 112 may be a p-type doped region. However, embodiments of the present inventive concept are not limited thereto.

The first doped region 111 may include a plurality of first fin-type active regions 121 protruding vertically, whereas the second doped region 112 may include a plurality of second fin-type active regions 122 protruding vertically.

The integrated circuit chip 1 may further include gate structures 231 and 232 disposed on the lower insulating film 210 (e.g., disposed directly thereon) and covering an upper portion of the channel region 110. The gate structures 231 and 232 may extend to perpendicularly intersect the channel region 110. For example, the gate structure 231 may cover an upper surface of the first fin-type active regions 121 and the gate structure 232 may cover an upper surface of the second fin-type active regions 122. Each of the gate structures 231 and 232 may include a gate electrode, a gate dielectric film, and a spacer. For example, in an embodiment, the gate electrode may include tungsten and aluminum, whereas the gate dielectric film may include high-k dielectrics such as a hafnium oxide. The spacer may include silicon nitride or silicon oxide. However, embodiments of the present inventive concept are not limited thereto.

The integrated circuit chip 1 may include source/drain regions disposed at opposite sides of the gate structures 231 and 232. The source/drain regions may be crystally grown at side and upper surfaces of the channel region 110 through an epitaxial process. For example, in an embodiment, the source/drain regions may include silicon or silicon germanium. However, embodiments of the present inventive concept are not limited thereto.

The integrated circuit chip 1 may further include an insulating capping pattern 220 disposed on the lower insulating film 210 while covering the gate structures 231 and 232. In some embodiments, an upper surface of the insulating capping pattern 220 may be flat. For example, in an embodiment, the insulating capping pattern 220 may be a silicon nitride film.

The integrated circuit chip 1 may include first vias V0 extending through the insulating capping pattern 220. At least a portion of the first vias V0 may expose a top of each of the gate structures 231 and 232 and/or the source/drain regions. In an embodiment of the present inventive concept, the gate structures 231 and 232 and/or the source/drain regions may be electrically connected, through the first vias V0, to a first wiring structure in the BEOL structure 300 which will be described later.

A structure disposed above the active surface 100A of the substrate 100 (e.g., the lower insulating film 210) and the insulating capping pattern 220 may be referred to as the “FEOL structure 200”.

The BEOL structure 300 may be disposed on the FEOL structure 200. For example, a lower surface of the BEOL structure 300 may directly contact an upper surface of the FEOL structure 200. The BEOL structure 300 may be formed through a BEOL process. The BEOL process may refer to a process for interconnecting individual elements, such as a transistor, a capacitor, a resistor, etc. in a manufacturing procedure for the integrated circuit chip 1. For example, in an embodiment, the BEOL process may include the silicidation of a region where a gate is formed, the source region and the drain region, the addition of dielectrics, planarization, formation of a hole, the addition of a metal layer, the formation of a contact plug, the formation of a passivation layer, etc. For example, the integrated circuit chip 1 may be packaged in a semiconductor package after execution of the BEOL process and, as such, may be used as an element for various applications. The BEOL process will be described in detail later.

In an embodiment, the BEOL structure 300 may include a plurality of multilayer wiring structures electrically connected to the FEOL structure 200, and an interlayer insulating film 303 for inter-insulating a portion of the plurality of multilayer wiring structures. The interlayer insulating film 303 may be formed to cover the FEOL structure 200.

As shown in the embodiment of FIG. 1, each of the plurality of multilayer wiring structures may include wiring layers M1, M2, M3, M4, . . . each including a plurality of wirings 301, and a plurality of vias 302 interconnecting the plurality of wirings 301 between adjacent ones of the plurality of wiring layers M1, M2, M3, M4, . . . . Each of the plurality of wiring layers M1, M2, M3, M4, . . . may be horizontally patterned. The plurality of vias 302 may extend in a vertically direction.

The number of the plurality of wiring layers M1, M2, M3, M4, . . . sequentially stacked in a vertical direction in each of the plurality of multilayer wiring structures may various numbers greater than or equal to 4 without being particularly limited.

In an embodiment, the interlayer insulating film 303 may be a silicon oxide film, a silicon nitride film, a silicon oxynitride film, or a combination thereof. In an embodiment of the present inventive concept, a portion of the layers constituting the interlayer insulating film 303 may be a passivation layer.

As shown in the embodiment of FIG. 1, the bumps 500 may be disposed on the BEOL structure 300. For example, a lower surface of the bumps 500 may directly contact an upper surface of the BEOL structure 300. The bumps 500 may be electrically connected to at least a portion of the plurality of wirings 301 in the BEOL structure 300. For example, in an embodiment, the bumps 500 may include chrome/chrome-copper alloy/copper (Cr/Cr—Cu/Cu), titanium-tungsten allay/copper (Ti—W/Cu), aluminum/nickel/copper (Al/Ni/Cu), or nickel. However, embodiments of the present inventive concept are not limited thereto. The bumps 500 may be formed through sputtering, electroplating, electroless plating, etc.

Hereinafter, the BEOL structure 300 will be described in detail.

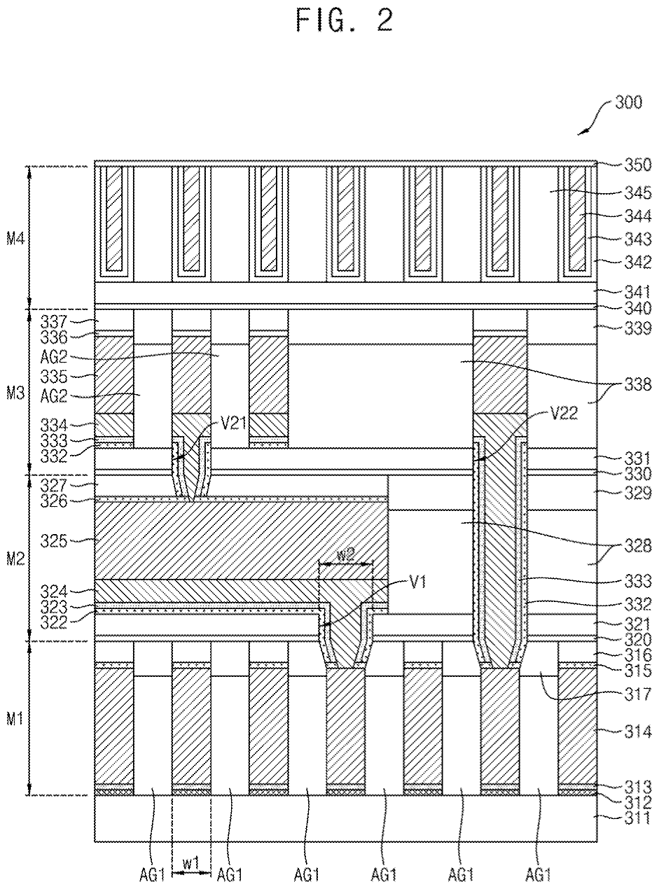

FIG. 2 is a cross-sectional view showing a portion of the BEOL structure in FIG. 1.

In an embodiment, the BEOL structure 300 may include a base layer 311, and a first wiring layer M1, a second wiring layer M2, a third wiring layer M3 and a fourth wiring layer M4 which are sequentially stacked from the base layer 311 in the vertical direction. The wiring layers M1 to M4 may be divided from one another by stop layers 320, 330 and 340 each disposed at a lowermost portion of a corresponding one of the wiring layers M2 to M4.

For example, in an embodiment, the base layer 311 may include an insulating material. In an embodiment, the insulating material may include silicon oxide, silicon nitride, silicon oxynitride, or a combination thereof. For example, the base layer 311 may be a passivation layer having a flat upper surface. However, embodiments of the present inventive concept are not limited thereto. For example, in an embodiment, the base layer 311 may include at least one semiconductor material selected from Si, Ge, SiGe, GaP, GaAs, SiC, SiGeC and InP, etc.

First, the first wiring layer M1, which includes a first wiring structure 314, will be described.

A first adhesive layer 312 may be disposed on the base layer 311. For example, the first adhesive layer 312 may be a film of an amorphous structure including at least one compound selected from WBx, MoBx, MoWBx, TaBx, NbBx, HfBx, ZrBx and CoB. However, embodiments of the present inventive concept are not limited thereto. For example, in an embodiment, the first adhesive layer 312 may include MoN or WN. In an embodiment, the first adhesive layer 312 may have a thickness in a range of about 0.3 to about 2 nm or a thickness in a range of about 0.5 to about 5 nm.

The first adhesive layer 312 may include functions for increasing the adhesiveness and alignment of a first seed layer 313 disposed over the first adhesive layer 312. However, embodiments of the present inventive concept are not limited thereto. For example, in some embodiments, the first adhesive layer 312 may be omitted.

The first seed layer 313 may be disposed on the first adhesive layer 312 (e.g., disposed directly thereon). For example, in an embodiment, the first seed layer 313 may include a compound selected from W, Mo, W rich-MoW, and Mo rich-MoW. In an embodiment, the first seed layer 313 may have a thickness in a range of about 0.5 to about 5 nm. For example, when the base layer 311 includes an oxide film, the first seed layer 313 may have a thickness in a range of about 4 nm or more for increasing a resistivity reduction effect.

In accordance with embodiments, the first adhesive layer 312 as described above may be applied under the first seed layer 313 to increase the grain size and alignment of the first seed layer 313.

The first wiring structure 314 may be disposed directly on the first seed layer 313. In an embodiment, a width w1 (e.g., length in a direction parallel to an upper surface of the base layer 311) of the first wiring structure 314 may be in a range of about 12 nm or less or in a range of about 10 nm or less. In an embodiment, the first wiring structure 314 having such a relatively small width may include Ru, Mo, W, or a combination thereof.

In an embodiment, the first wiring structure 314 may include an MoW alloy. For example, the composition of the MoW alloy may be in a range of about 25 to about 75 at % for Mo. In this embodiment, the MoW alloy may exhibit high corrosion resistance and low resistivity.

As shown in the embodiment of FIG. 2, the first wiring structure 314 may be provided in plural in the first wiring layer M1. In this embodiment, first wiring structures 314 may be horizontally spaced apart from one another (e.g., in a direction parallel to an upper surface of the base layer 311). In an embodiment, the first adhesive layer 312 and the first seed layer 313 disposed under the first wiring structures 314 may also be patterned such that patterned portions thereof may be spaced apart from one another at positions where the first wiring structures 314 are disposed. For example, the lateral side walls of the first adhesive layer 312, the first seed layer 313 and the first wiring structures 314 may be aligned with each other.

A first capping pattern 315 may be disposed on each of the first wiring structures 314. A lower portion of the first capping pattern 315 may directly contact upper portions of the first wiring structures 314. For example, in an embodiment, the first capping pattern 315 may include an oxide such as at least one compound selected from SiO₂, Al₂O₃, TiOx, TaOx, HfOx, ZrOx, MgO, etc. or a nitride such as at least one compound selected from SiN, TiN, TaN, etc. The first capping pattern 315 as described above may prevent oxidation or nitrification of an upper surface of the first wiring structure 314, and may prevent a damage layer causing variation in properties of the first wiring structure 314 (e.g., an increase in resistivity) from being formed on the first wiring structure 314.

A first hard mask pattern 316 may be disposed on the first capping pattern 315. A lower portion of the first hard mask pattern 316 may directly contact an upper portion of the first capping pattern 315. For example, in an embodiment, the first hard mask pattern 316 may include SiN or SiO₂.

A first cover member 317 may be disposed around the first hard mask pattern 316. The first cover member 317 may fill a region around the first hard mask pattern 316. In some embodiments, the first cover member 317 may contact upper portions of the first wiring structures 314 corresponding thereto.

The first cover member 317 may be disposed around the first hard mask pattern 316 and, as such, may form a first air gap AG1 between the corresponding first wiring structures 314. For example, the first cover member 317 may include an insulating oxide material that has a low step coverage to form the first air gap AG1. A portion of the first wiring structure 314 may be electrically connected to the FEOL structure 200, such as a transistor of the FEOL structure.

Next, the second wiring layer M2, which includes a second wiring structure 324/325, will be described.

A first stop layer 320 may be disposed on the first cover member 317 and the first hard mask pattern 316. The lower surface of the first stop layer 320 may directly contact upper surfaces of the first cover member 317 and the first hard mask pattern 316. For example, in an embodiment, the first stop layer 320 may be an etch-stop layer and may include silicon oxide.

A first insulating layer 321 may be disposed on the first stop layer 320. For example, a lower surface of the first insulating layer 321 may directly contact an upper surface of the first stop layer 320. In an embodiment, the first insulating layer 321 may be a silicon oxide film, a silicon nitride film, a silicon oxynitride film, or a combination thereof. For example, the first insulating layer 321 may be a passivation layer having a flat upper surface.

In an embodiment, the BEOL structure 300 may include a second via V1 extending through at least a portion of the first insulating layer 321, the first stop layer 320, the first hard mask pattern 316 and the first capping pattern 315. For example, the second via V1 may expose an upper surface of a portion of the first wiring structures 314. In an embodiment, a width w2 (e.g., length in the horizontal direction) of the second via V1 may be in a range of about 16 nm or less.

A second adhesive layer 322 may be disposed on a portion of the first insulating layer 321 (e.g., disposed directly thereon), and a second seed layer 323 may be disposed on the second adhesive layer 322 (e.g., disposed directly thereon). However, embodiments of the present inventive concept are not limited thereto. For example, in some embodiments, the second adhesive layer 322 may be omitted.

In an embodiment, the second adhesive layer 322 may include MoN or WN. The second seed layer 323 may include MoNx, WNx, Mo or W. In an embodiment, the thickness of the second seed layer 323 may be in a range of about 0.5 to about 5 nm. Each of the second adhesive layer 322 and the second seed layer 323 may be disposed on a portion of the first insulating layer 321 and in the second via V1.

The second wiring structure 324/325 may be disposed directly on the second seed layer 323. The second wiring structure 324/325 may include a first metal layer 324 and a second metal layer 325 which are sequentially stacked. For example, a lower surface of the second metal layer 325 may directly contact an upper surface of the first metal layer 324.

For example, the first metal layer 324 may be disposed directly on the second seed layer 323. The first metal layer 324 may fill the second via V1. In an embodiment, the first metal layer 324 may be a gap-fill metal. In an embodiment of the present inventive concept, the first metal layer 324 may be connected to a portion (e.g., at least one) of the first wiring structures 314 through the second via V1. An upper surface of the first metal layer 324 may be flat. The thickness of the first metal layer 324 may be in a range of about 20 to about 70 nm in a region where the second via V1 is not formed. The second metal layer 325 may be disposed on the first metal layer 324 (e.g., disposed directly thereon). In an embodiment, the thickness of the second metal layer 325 may be in a range of about 20 to about 70 nm.

In an embodiment, each of the first metal layer 324 and the second metal layer 325 may include Ru, Mo, W, or an MoW alloy. In an embodiment, the composition of the MoW alloy may be in a range of about 25 to about 75 at % for Mo.

In an embodiment, the first metal layer 324 and the second metal layer 325 may be formed through different deposition processes, respectively. In some embodiments, the resistivity of the first metal layer 324 and the resistivity of the second metal layer 325 may be different.

A second capping pattern 326 may be disposed on the second metal layer 325 (e.g., disposed directly thereon). For example, in an embodiment, the second capping pattern 326 may include an oxide such as at least one compound selected from SiO₂, Al₂O₃, TiOx, TaOx, HfOx, ZrOx, MgO, etc. or a nitride such as at least one compound selected from SiN, TiN, TaN, etc. The second capping pattern 326 as described above may prevent oxidation or nitrification of an upper surface of the second wiring structure 324/325, and may prevent a damaged layer causing variation in properties of the second wiring structure 324/325 from being formed on the second wiring structure 324/325.

A second hard mask pattern 327 may be disposed on the second capping pattern 326 (e.g., disposed directly thereon). For example, in an embodiment, the second hard mask pattern 327 may include SiN or SiO₂. However, embodiments of the present inventive concept are not limited thereto.

A second insulating layer 328 may be disposed on another portion of the first insulating layer 321. The second insulating layer 328 may be disposed adjacent to the second wiring structure 324/325 (e.g., in a horizontal direction). In an embodiment, the second insulating layer 328 may be a silicon oxide film, a silicon nitride film, a silicon oxynitride film, or a combination thereof. For example, the second insulating layer 328 may be a passivation layer having a flat upper surface.

In some embodiments, a via (e.g., a fourth via V22) extending through the second insulating layer 328 may be formed at the second wiring layer M2. This feature will be described later.

A second cover member 329 may be disposed around the second hard mask pattern 327. The second cover member 329 may fill a region around the second hard mask pattern 327. The second hard mask pattern 327 may be disposed on the second insulating layer 328 (e.g., disposed directly thereon). In some embodiments, the second cover member 329 may directly contact an upper portion of the second wiring structure 324/325.

The second cover member 329 may be formed around the second hard mask pattern 327 and, as such, may form an air gap between corresponding ones of a plurality of second wiring structures 324/325. For example, the second cover member 329 may include an insulating oxide material exhibiting low step coverage for forming an air gap.

Next, a third wiring layer M3, which includes a third wiring structure 334/335, will be described.

A second stop layer 330 may be disposed on the second cover member 329 and the second hard mask pattern 327 (e.g., disposed directly thereon). For example, in an embodiment, the second stop layer 330 may be an etch stop layer and, as such, may include silicon oxide.

A third insulating layer 331 may be disposed on the second stop layer 330 (e.g., disposed directly thereon). In this embodiment, the third insulating layer 331 may be a silicon oxide film, a silicon nitride film, a silicon oxynitride film, or a combination thereof. For example, the third insulating film 331 may be a passivation layer having a flat upper surface.

In an embodiment, the BEOL structure 300 may include a third via V21 extending through at least a portion of the third insulating layer 331, the second stop layer 330, the second hard mask pattern 327 and the second capping pattern 326. For example, the third via V21 may expose an upper surface of a portion of the second wiring structures 324/325 (e.g., the second metal layers 325). In an embodiment, the width of the third via V21 (e.g., length in the horizontal direction) may be in a range of about 16 nm or less.

In an embodiment, the BEOL structure 300 may include a fourth via V22 extending through the third insulating layer 331, the second stop layer 330, the second hard mask pattern 327, the second capping pattern 326, the second insulating layer 328, the first insulating layer 321, the first stop layer 320, the first hard mask pattern 316 and the first capping pattern 315. The fourth via V22 may be referred to as a “super-via”.

A third adhesive layer 332 may be disposed on a portion of the third insulating layer 331, and a third seed layer 333 may be disposed on the third adhesive layer 332 (e.g., disposed directly thereon). However, embodiments of the present inventive concept are not limited thereto. For example, in some embodiments, the third adhesive layer 332 may be omitted.

The third adhesive layer 332 may include MoN or WN. The third seed layer 333 may include MoNx, WNx, Mo or W. In an embodiment, the thickness of the third seed layer 333 may be in a range of about 0.5 to about 5 nm. The third adhesive layer 332 and the third seed layer 333 may be disposed on a portion of the third insulating layer 331 and in the third via V21 and the fourth via V22.

The third wiring structure 334/335 may be disposed on the third seed layer 333 (e.g., disposed directly thereon). The third wiring structure 334/335 may include a third metal layer 334 and a fourth metal layer 335 which are sequentially stacked (e g., in the vertical direction).

The third metal layer 334 may be disposed directly on the third seed layer 333. The third metal layer 334 may fill the third via V21 and the fourth via V22. In some embodiments, the third metal layer 334 may be connected to a portion (e.g., at least one) of the second wiring structures 324/325, such as the second metal layers 325 by the third via V21. In an embodiment, the third metal layer 334 may be connected to a portion (e.g., at least one) of the first wiring structures 314 by the fourth via V22. An upper surface of the third metal layer 334 may be flat. In an embodiment, the thickness of the third metal layer 334 may be in a range of about 20 to about 70 nm in a region where neither the third via V21 nor the fourth via V22 is formed.

The fourth metal layer 335 may be disposed on the third metal layer 334. In an embodiment, the thickness of the fourth metal layer 335 may be in a range of about 20 to about 70 nm.

In an embodiment, each of the third metal layer 334 and the fourth metal layer 335 may include Ru, Mo, W, or a combination thereof, such as an MoW alloy. For example, the composition of the MoW alloy may be in a range of about 25 to about 75 at % for Mo.

In an embodiment, the third metal layer 334 and the fourth metal layer 335 may be formed through different processes, respectively. In some embodiments, the resistivity of the third metal layer 334 and the resistivity of the fourth metal layer 335 may be different.

In an embodiment, the first metal layer 324 and the third metal layer 334 may be formed through the same process, and the second metal layer 325 and the fourth metal layer 335 may be formed through the same process. In an embodiment, the resistivity of the first metal layer 324 and the resistivity of the third metal layer 334 may be equal, and the resistivity of the second metal layer 325 and the resistivity of the fourth metal layer 335 may be equal.

A third capping pattern 336 may be disposed on the fourth metal layer 335. For example, the third capping pattern 336 may include an oxide such as at least one compound selected from SiO₂, Al₂O₃, TiOx, TaOx, HfOx, ZrOx, MgO, etc. or a nitride such as at least one compound selected from SiN, TiN, TaN, etc. The third capping pattern 336 as described above may prevent oxidation or nitrification of an upper surface of the third wiring structure 334/335, and may prevent a damage layer causing variation in properties of the third wiring structure 334/335 from being formed on the third wiring structure 334/335.

A third hard mask pattern 337 may be disposed on the third capping pattern 336 (e.g., disposed directly thereon). For example, in an embodiment, the third hard mask pattern 337 may include SiN or SiO₂. However, embodiments of the present inventive concept are not limited thereto.

A fourth insulating layer 338 may be disposed on another portion of the third insulating layer 331. The fourth insulating layer 338 may be disposed adjacent to the third wiring structure 334/335 (e.g., in the horizontal direction). In an embodiment, the fourth insulating layer 338 may be a silicon oxide film, a silicon nitride film, a silicon oxynitride film, or a combination thereof. For example, the fourth insulating layer 338 may be a passivation layer having a flat upper surface.

A third cover member 339 may be disposed around the third hard mask pattern 337. The third cover member 339 may fill a region around the third hard mask pattern 337. The third hard mask pattern 337 may be disposed on the fourth insulating layer 338 (e.g., disposed directly thereon). In some embodiments, the third cover member 339 may directly contact an upper portion of the third wiring structure 334/335.

The third cover member 339 may be disposed around the third hard mask pattern 337 and, as such, may form a second air gap AG2 between corresponding ones of a plurality of third wiring structures 334/335. For example, the third cover member 339 may include an insulating oxide material exhibiting low step coverage for forming the second air gap AG2.

Next, a fourth wiring layer M4, which includes a fourth wiring structure 342/343/344, will be described.

A third stop layer 340 may be disposed on the third cover member 339 and the third hard mask pattern 337 (e.g., disposed directly thereon). For example, the third stop layer 340 may be an etch stop layer and may include silicon oxide.

A fifth insulating layer 341 may be disposed on the third stop layer 340. In an embodiment, the fifth insulating layer 341 may be a silicon oxide film, a silicon nitride film, a silicon oxynitride film, or a combination thereof. However, embodiments of the present inventive concept are not limited thereto. For example, the fifth insulating layer 341 may be a passivation layer having a flat upper surface.

A plurality of fourth wiring structures 342/343/344 may be disposed on the fifth insulating layer 341. Each of the fourth wiring structures 342/343/344 may include a core metal 344, a liner film 343 surrounding the core metal 344, and a barrier film 342 surrounding the liner film 343.

In an embodiment, the core metal 344 may include Cu, Ir, Rh, or Co. In an embodiment, the plurality of fourth wiring structures 342/343/344 may include a material that is different from the material of the first wiring structure 314. In an embodiment, the width of the core metal 344 (e.g., length in the horizontal direction) may be greater than about 12 nm. In an embodiment, the liner film 343 may include Co or Ru. In an embodiment, the barrier film 342 may include a low resistance metal such as Cu, Al or W, or metal nitride such as titanium nitride, tantalum nitride, etc.

In an embodiment, each of the fourth wiring structures 342/343/344 may be formed through a damascene process. However, embodiments of the present inventive concept are not limited thereto. Each of the fourth wiring structures 342/343/344 may be formed through different deposition processes than the first wiring structures 314. An insulating pattern 345 may be disposed between adjacent ones of the plurality of fourth wiring structures 342/343/344.

In an embodiment, the fourth wiring structure 342/343/344 may not include an air gap.

A fourth stop layer 350 may be disposed on the fourth wiring structure 342/343/344 and the insulating pattern 345 (e.g., disposed directly thereon). In an embodiment, when a wiring layer is successively formed on the fourth stop layer 350, the wiring layer may include the same wiring structure as the fourth wiring structure 342/343/344.

Hereinafter, a method for manufacturing the BEOL structure 300 will be described in detail.

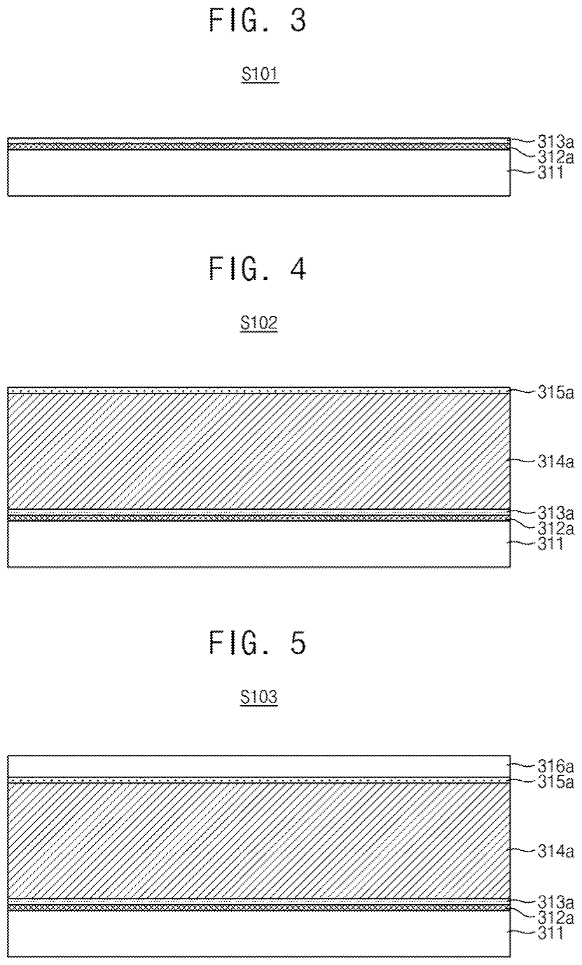

FIGS. 3 to 22 are cross-sectional views explaining BEOL structure manufacturing procedures according to embodiments of the present inventive concept, respectively. In the following description, FIG. 2 may also be referred to.

Referring to operation S101 of FIG. 3, in an embodiment, a first adhesive material 312a may be formed on a base layer 311, and a first seed material 313a may be deposited on the first adhesive material 312a. Here, the first adhesive material 312a may include the same material as the above-described first adhesive layer 312, and the first seed material 313a may include the same material as the above-described first seed layer 313.

Referring to operation S102 of FIG. 4, a first metal film 314a may be deposited on the first seed material 313a, and a first capping material 315a may be formed on the first metal film 314a. For example, in an embodiment, the first capping material 315a may be formed through an in-situ encapsulation technology. However, embodiments of the present inventive concept are not limited thereto. Here, the first metal film 314a may include the same material as the first wiring structure 314, and the first capping material 315a may include the same material as the first capping pattern 315.

In an embodiment, the first metal film 314a may be formed through a subtractive metal wiring process. For example, the first metal film 314a may be deposited through a physical deposition process (hereinafter referred to as a “PVD process”). In this embodiment, the deposition temperature may be in a range of about 200 to about 550° C. When the first metal film 314a is deposited using such a relatively high temperature process, the grain size and alignment of the first metal film 314a may be increased.

In accordance with an embodiment, after deposition of the first metal film 314a, an H₂, H₂ plasma or H radical annealing process may be performed in a range of about 400 to about 750° C. to additionally increase the size of grains in the first metal film 314a or to remove impurities from the first metal film 314a.

In accordance with embodiments, after deposition of the first metal film 314a, a first capping material 315a may be formed in the same system to prevent surface oxidation and nitrification of the first metal film 314a.

Referring to operation S103 of FIG. 5, a first hard mask material 316a may be formed on the first capping material 315a. In an embodiment, the first hard mask material 316a may include the same material as the above-described first hard mask pattern 316.

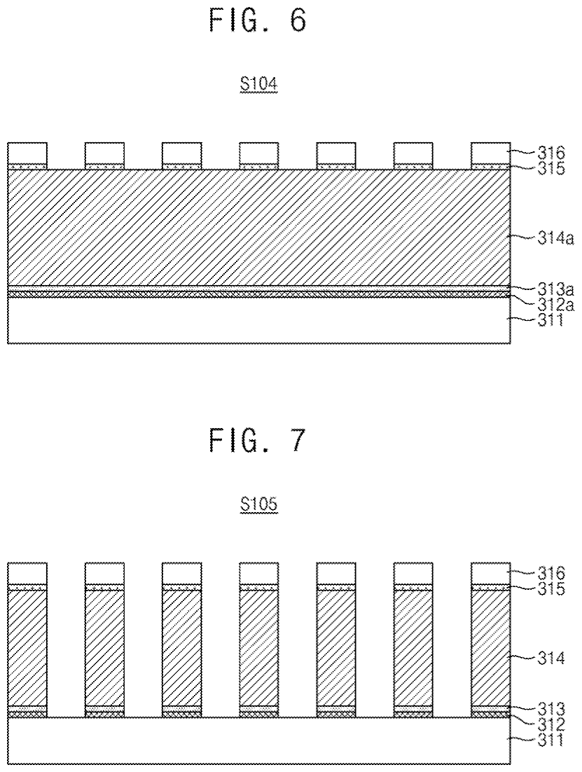

Referring to operation S104 of FIG. 6, a primary etching process may be performed on the first capping material 315a and the first hard mask material 316a. As portions of the first capping material 315a and the first hard mask material 316a are removed, the first capping material 315a and the first hard mask material 316a may form the above-described first capping pattern 315 and the above-described first hard mask pattern 316, respectively.

Referring to operation S105 of FIG. 7, a secondary etching process may be performed for portions of the first metal film 314a, the first seed material 313a and the first adhesive material 312a. In an embodiment, the secondary etching process may use a subtractive metal etching method. As the portions of the first metal film 314a, the first seed material 313a and the first adhesive material 312a are removed, the first metal film 314a, the first seed material 313a and the first adhesive material 312a may form the above-described first wiring structure 314, the above-described first seed layer 313 and the above-described first adhesive layer 312, respectively.

In an embodiment, to prevent damage to, and oxidation and nitrification of a side surface of the first metal film 314a in the secondary etching process, a subtractive metal etching process may be performed after formation of the first metal film 314a, and the first capping pattern 315 may be subsequently formed on the first wiring structure 314.

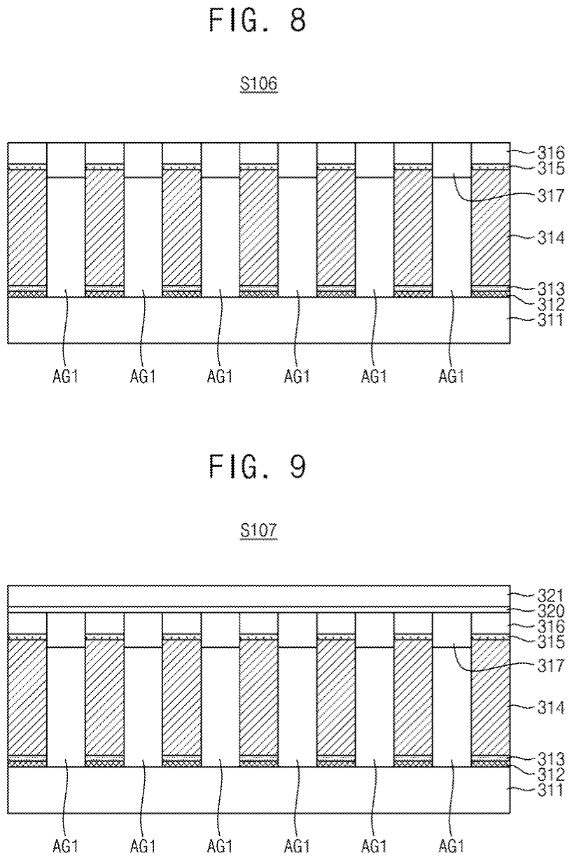

Referring to operation S106 of FIG. 8, a first cover member 317 may be formed around the first hard mask pattern 316 to form a first air gap AG1 between the first wiring structures 314. In an embodiment, the first cover member 317 may be formed to surround side and upper portions of the first hard mask pattern 316, and an upper surface of the first cover member 317 may be ground. In an embodiment, the first cover member 317 and the first air gap AG1 may be formed in such a manner that a material easily decomposable by heat is formed around the first hard mask pattern 316, the first cover member 317 is then formed on the material, and the material is finally removed at a high temperature.

Referring to operation S107 of FIG. 9, a first stop layer 320 and a first insulating layer 321 may be sequentially deposited on the first cover member 317 and the first hard mask pattern 316.

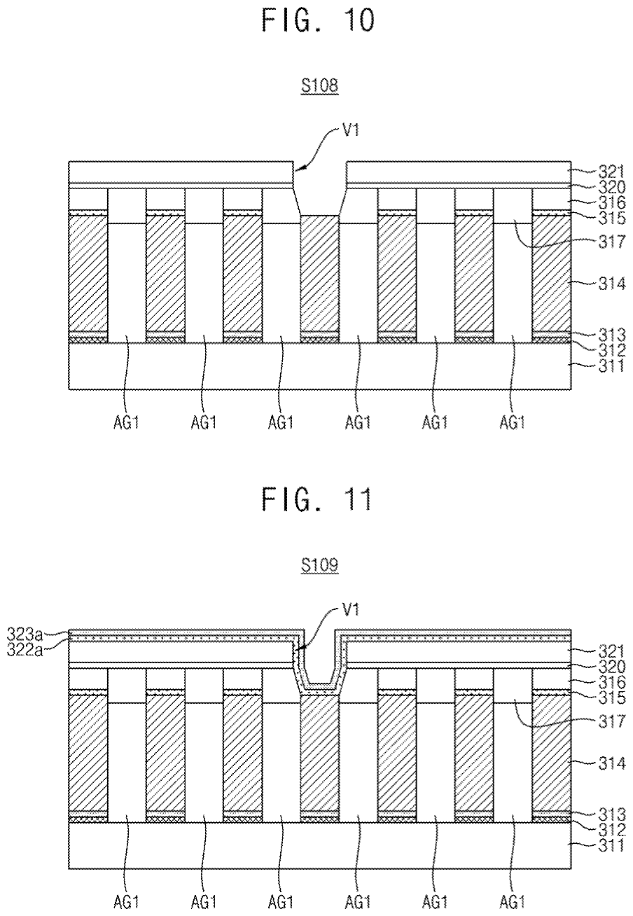

Referring to operation S108 of FIG. 10, portions of the first insulating layer 321, the first stop layer 320, the first hard mask pattern 316 and the first capping pattern 315 may be removed. In an embodiment, a region in which the portions are removed may form the above-described second via V1.

Referring to operation S109 of FIG. 11, a second adhesive material 322a may be formed on the first insulating layer 321 and in the second via V1. A second seed material 323a may then be formed on the second adhesive material 322a. In this embodiment, the second adhesive material 322a may include the same material as the above-described second adhesive layer 322, and the second seed material 323a may include the same material as the above-described second seed layer 323.

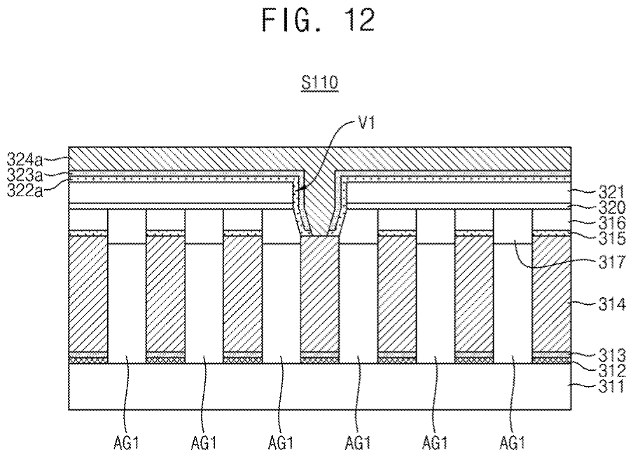

Referring to operation S110 of FIG. 12, a second metal film 324a may he deposited on the second seed material 323a. In this embodiment, the second metal film 324a may be the same material as the above-described first metal layer 324.

In an embodiment, the second metal film 324a may be formed through a semi-damascene process. For example, the second metal film 324a may be deposited through an atomic layer deposition process (hereinafter referred to as an “ALD process”) or a chemical vapor deposition process (hereinafter referred to as a “CVD process”). However, embodiments of the present inventive concept are not limited thereto. The second metal film 324a may be formed to fill the second via V1.

In an embodiment, when the second metal film 324a is deposited through an ALD process or CVD process, the deposition temperature may be in a range of about 200 to about 750° C. When the second metal film 324a is deposited through such a relatively high temperature process, the grain size and alignment of the first metal film 314a may be increased.

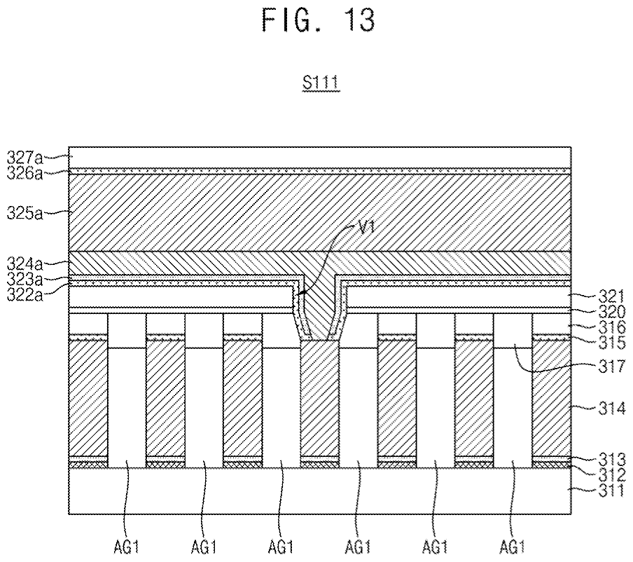

Referring to operation S111 of FIG. 13, a third metal film 325a may be deposited on the second metal film 324a, and a second capping material 326a may be formed on the third metal film 325a. In an embodiment, the third metal film 325a may include the same material as the above-described second metal layer 325, and the second capping material 326a may include the same material as the above-described second capping pattern 326.

In an embodiment, the third metal film 325a may be formed through a subtractive metal process. For example, the third metal film 325a may be deposited through a physical deposition process (hereinafter referred to as a “PVD process”). In this embodiment, the deposition temperature may be in a range of about 200 to about 550° C.

When the second metal film 324a and the third metal film 325a are deposited through a relatively high temperature process, as described above, the grain size and alignment of the first metal film 314a may be increased. In an embodiment, after formation of the second metal film 324a or the third metal film 325a, an H₂, H₂ plasma or radical annealing process may be performed in a range of about 400 to about 750° C. to additionally increase the size of grains in the second metal film 324a or the third metal film 325a or to remove impurities from the second metal film 324a or the third metal film 325a.

In an embodiment, after deposition of the third metal film 325a, a second capping material 326a may be formed in the same system to prevent surface oxidation and nitrification of the third metal film 325a.

Thereafter, a second hard mask material 327a may be formed on the second capping material 326a. In this embodiment, the second hard mask material 327a may include the same material as the above-described second hard mask pattern 327.

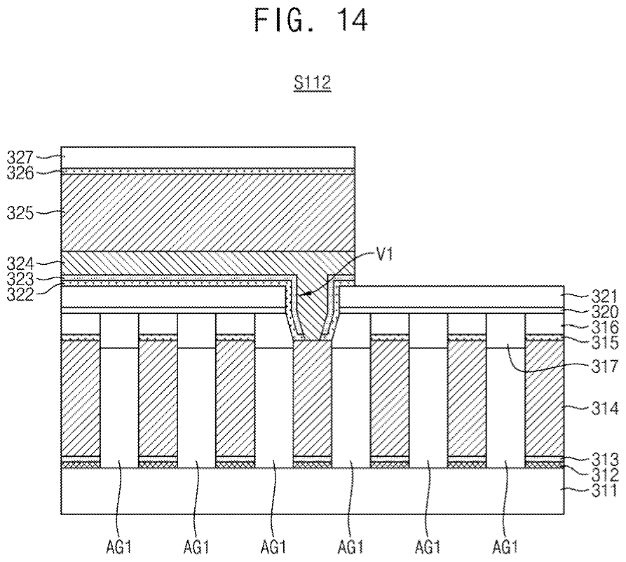

Referring to operation S112 of FIG. 14, a third etching process may be performed for portions of the second hard mask material 327a, the second capping material 326a, the third metal film 325a, the second metal film 324a, the second seed material 323a and the second adhesive material 322a. In an embodiment, the third etching process may be performed under the condition that the third etching process is divided into an etching process for the second capping material 326a and the second hard mask material 327a and an etching process for the second metal film 324a, the third metal film 325a, the second seed material 323a and the second adhesive material 322a.

In an embodiment, the third etching process may use a subtractive metal etching method. As the portions of the second metal film 324a and the third metal film 325a are removed, the second metal film 324a and the third metal film 325a may form the above-described second wiring structure 324/325. As the portions of the second seed material 323a and the second adhesive material 322a are removed, the second seed material 323a and the second adhesive material 322a may form the above-described second seed layer 323 and the above-described second adhesive layer 322, respectively.

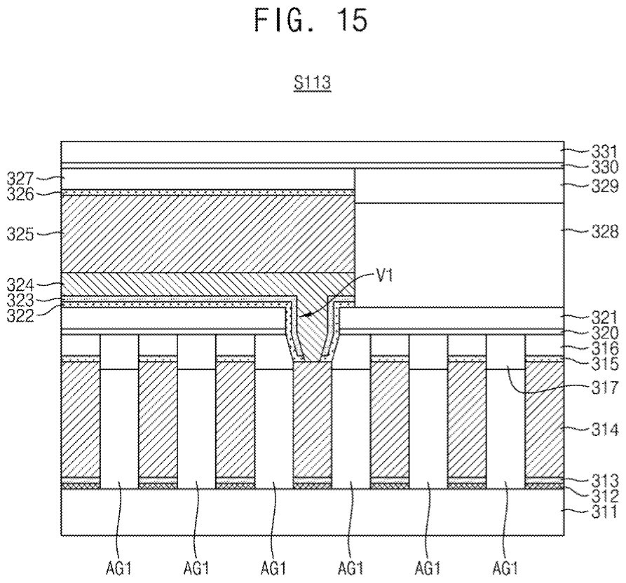

Referring to operation S113 of FIG. 15, a second insulating layer 328 may be formed on the first insulating layer 321 in at least a portion of a region that the portions as described above are removed through the third etching process. A second cover member 329 may be formed around the second hard mask pattern 327 and on the second insulating layer 328. A second stop layer 330 and a third insulating layer 331 may then be deposited on the second cover member 329 and the second hard mask pattern 327.

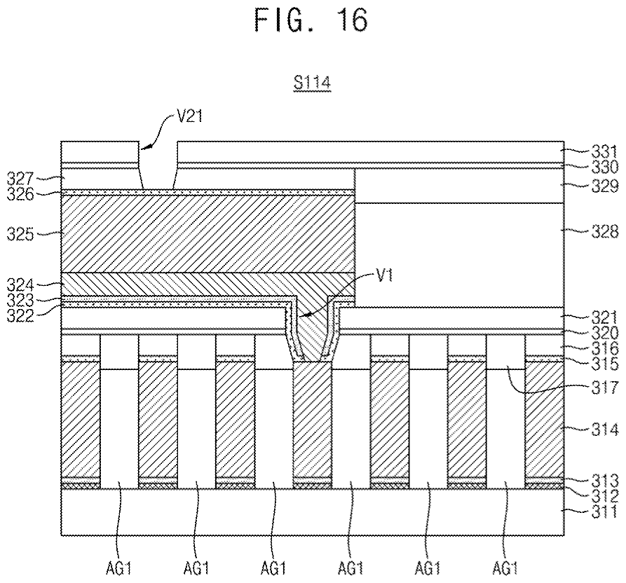

Referring to operation S114 of FIG. 16, portions of the third insulating layer 331, the second stop layer 330, the second hard mask pattern 327 and the second capping pattern 326 may be removed. In an embodiment, a region that the portions are removed may form the above-described third via V21.

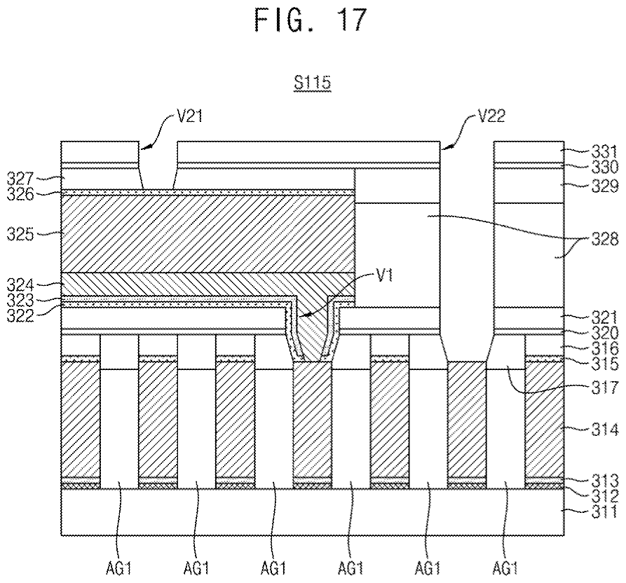

Referring to operation S115 of FIG. 17, portions of the third insulating layer 331, the second stop layer 330, the second hard mask pattern 327, the second capping pattern 326, the second insulating layer 328, the first insulating layer 321, the first stop layer 320, the first hard mask pattern 316 and the first capping pattern 315 may be removed. In an embodiment, a region that the portions are removed may form the above-described fourth via V22.

Although operation S114 and operation S115 are shown as being performed such that operation S115 follows operation S114, the sequence of operations S114 and S115 is not limited to the above-described condition. For example, in some embodiments, operation S115 may be performed before operation S114 or operation S114 and operation S115 may be simultaneously performed.

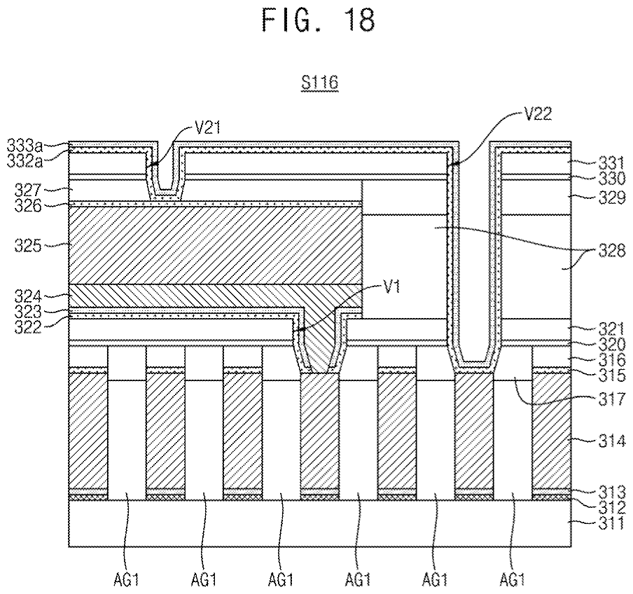

Referring to operation S116 of FIG. 18, a third adhesive material 332a may be formed on the third insulating layer 331 and in the fourth via V22 and the third via V21. A third seed material 333a may then be formed on the third adhesive material 332a. In an embodiment, the third adhesive material 332a may include the same material as the above-described third adhesive layer 332, and the third seed material 333a may include the same material as the above-described third seed layer 333.

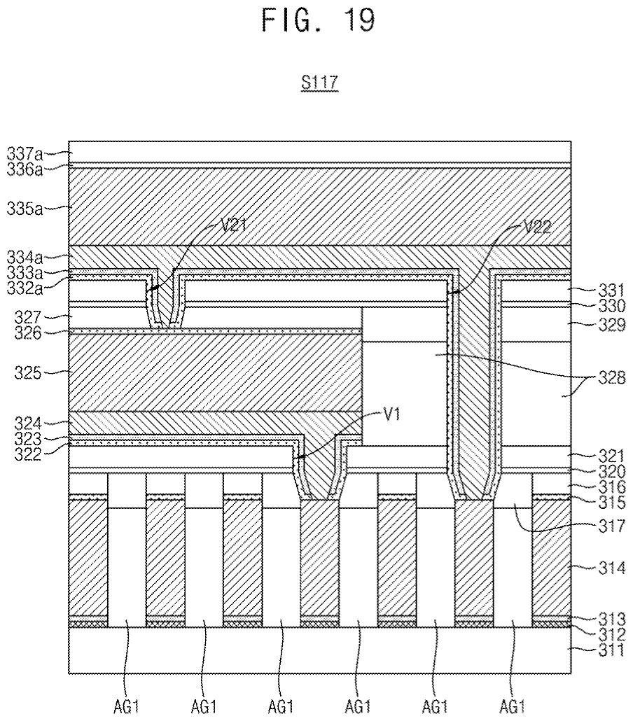

Referring to operation S117 of FIG. 19, a fourth metal film 334a may be deposited on the third seed material 333a. In an embodiment, the fourth metal film 334a may include the same material as the above-described third metal layer 334.

In an embodiment, the fourth metal film 334a may be formed through a semi-damascene process. For example, the fourth metal film 334a may be deposited through an ALD process or a CVD process. The fourth metal film 334a may be formed to fill the third via V21 and the fourth via V22.

In an embodiment when the fourth metal film 334a is deposited through an ALD process or a CVD process, the deposition temperature may be in a range of about 200 to about 750° C.

Thereafter, a fifth metal film 335a may be deposited on the fourth metal film 334a, and a third capping material 336a may be formed on the fifth metal film 335a. In an embodiment, the fifth metal film 335a may include the same material as the above-described fourth metal layer 335, and the third capping material 336a may include the same material as the above-described third capping pattern 336.

In an embodiment, the fifth metal film 335a may be formed through a subtractive metal process. For example, the fifth metal film 335a may be deposited through a PVD process. In an embodiment, the deposition temperature may be in a range of about 200 to about 550° C.

A third hard mask material 337a may their be formed on the third capping material 336a. In an embodiment, the third hard mask material 337a may include the same material as the above-described third hard mask pattern 337.

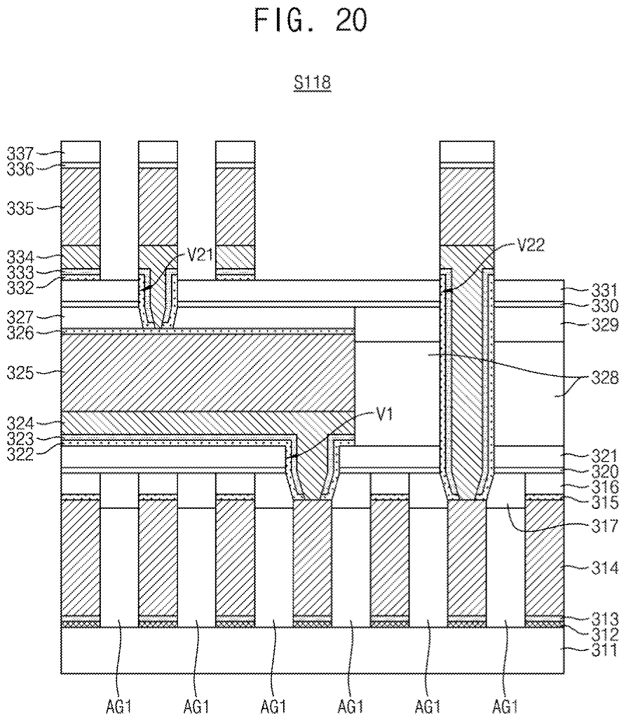

Referring to operation S118 of FIG. 20, a fourth etching process may be performed for portions of the third hard mask material 337a, the third capping material 336a, the fifth metal film 335a, the fourth metal film 334a, the third seed material 333a, and the third adhesive material 332a. In an embodiment, the fourth etching process may be performed under the condition that the fourth etching process is divided into an etching process for the third capping material 336a and the third hard mask material 337a and an etching process for the fourth metal film 334a, the fifth metal film 335a, the third seed material 333a, and the third adhesive material 332a.

In an embodiment, the fourth etching process may use a subtractive metal etching method. As the portions of the fourth metal film 334a and the fifth metal film 335a are removed, the fourth metal film 334a and the fifth metal film 335a may form the above-described third wiring structure 334/335. As the portions of the third seed material 333a and the third adhesive material 332a are removed, the third seed material 333a and the third adhesive material 332a may form the above-described third seed layer 333 and the above-described adhesive layer 332, respectively.

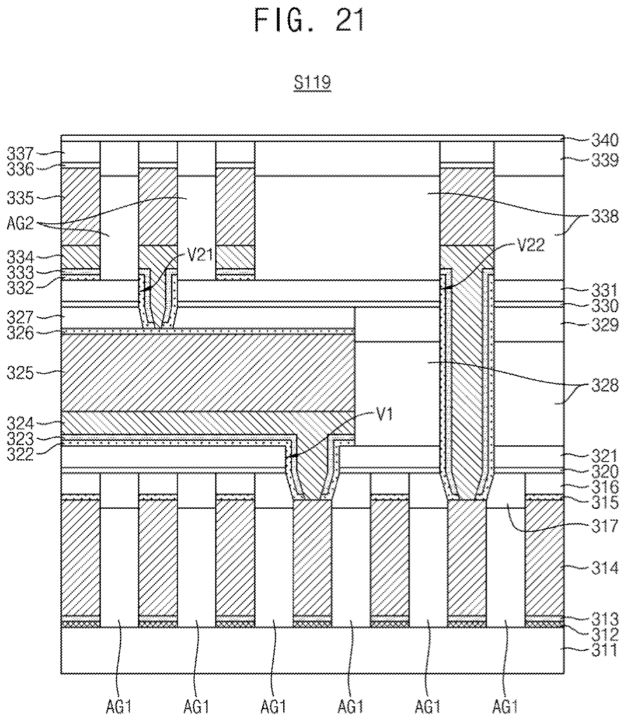

Referring to operation S119 of FIG. 21, a fourth insulating layer 338 may be formed on the third insulating layer 331 in at least a portion of a region that the portions as described above are removed through the fourth etching process, and a third cover member 339 may be formed around the third hard mask pattern 337 and on the third. insulating layer 331. A third stop layer 340 may then be deposited on the third cover member 339 and the third hard mask pattern 337.

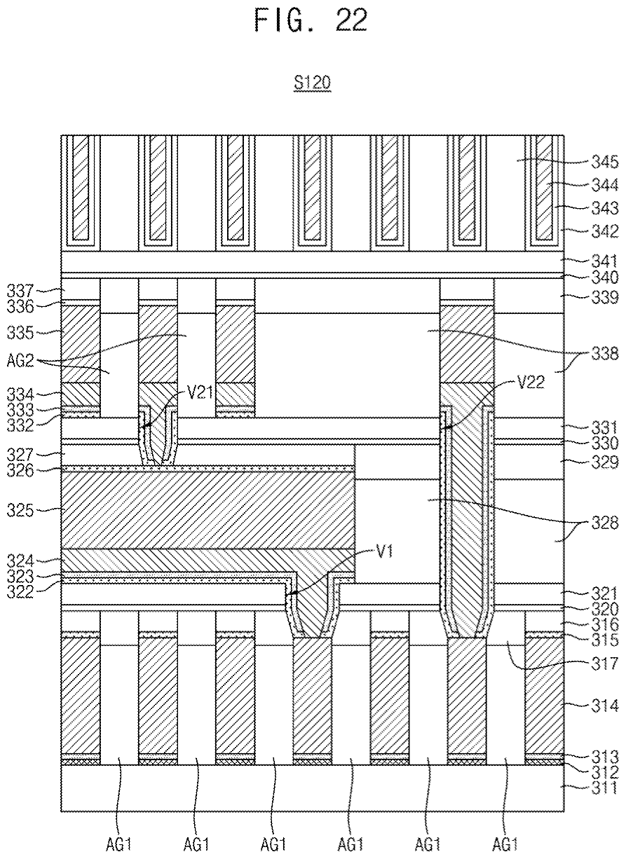

Referring to operation S120 of FIG. 22, a fourth wiring structure 342/343/344 may be formed on the third stop layer 340. In an embodiment, the fourth wiring structure 342/343/344 may be formed through a damascene process. However, embodiments of the present inventive concept are not limited thereto.

Hereinafter, a BEOL structure according to an embodiment of the present inventive concept will be described. In the following description, a repeated description of elements that are identical or similar to those of FIG. 2 may be omitted for convenience of explanation, and such identical or similar elements will be designated by reference numerals identical or similar to those of FIG. 2.

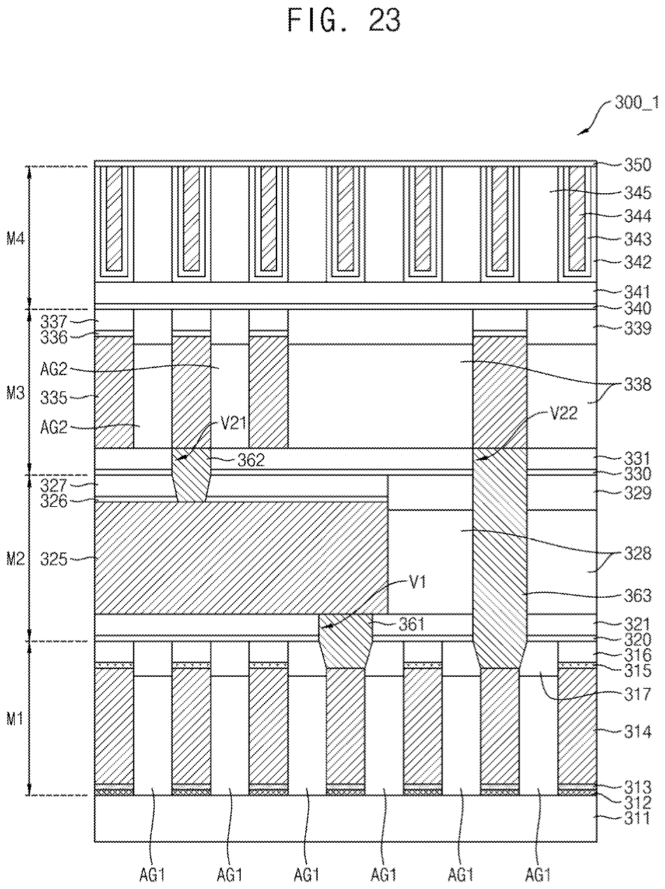

FIG. 23 is a cross-sectional view showing a portion of a BEOL structure according to an embodiment of the present inventive concept.

Referring to FIG. 23, a BEOL structure 300_1 according to an embodiment differs from the BEOL structure 300 according to the embodiment of FIG. 2 in that each of a second wiring structure 325 and a third wiring structure 335 have a single-layer structure.

In an embodiment, the BEOL structure 300 may include filling metals 361, 362 and 363 filling second to fourth vias V1, V21 and V22, respectively. For example, the second via V1 may be filled with a first filling metal 361, the third via V21 may be filled with a second filling metal 362, and the fourth via V22 may be filled with a third filling metal 363. In an embodiment, each of the filling metals 361, 362 and 363 may include Mo, W, Ru, Co, Cu or MoW. However, embodiments of the present inventive concept are not limited thereto. In an embodiment, each of the filling metals 361, 362 and 363 may be formed through a single damascene process.

In an embodiment, each of a first wiring structure 314 and the second and third wiring structures 325 and 335 may have a single-layer structure. Each of the first to third wiring structures 314, 325 and 335 may be formed through a PVD process, an ALD process or a CVD process.

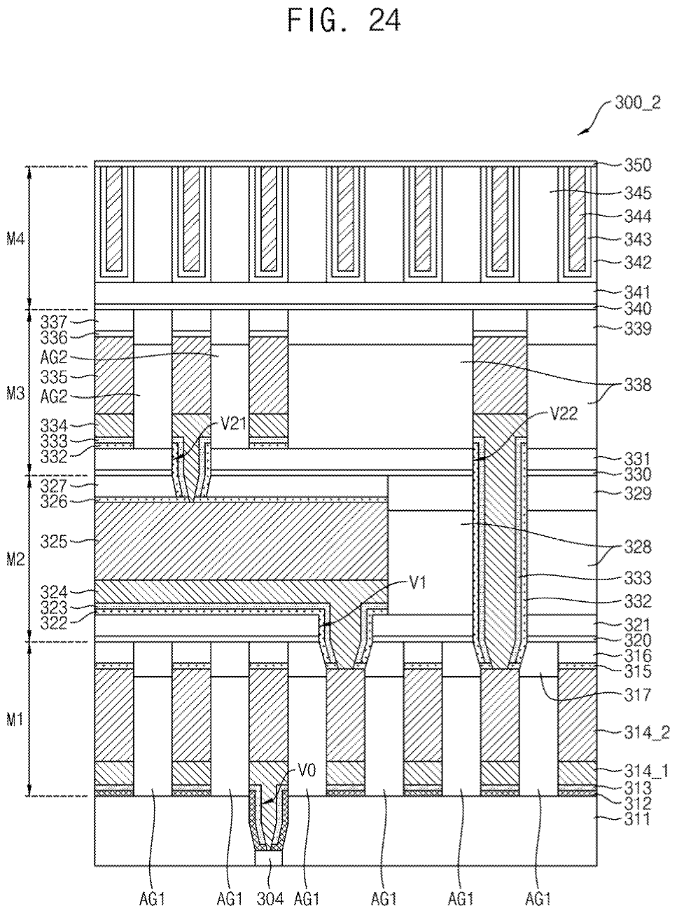

FIG. 24 is a cross-sectional view showing a portion of a BEOL structure according to an embodiment of the present inventive concept.

Referring to FIG. 24, a BEOL structure 300_2 according to the embodiment differs from the BEOL structure 300 according to the embodiment of FIG. 2 in that a first wiring structure 314_1/314_2 has a multilayer structure.

A first via V0 may be formed at a base layer 311 such that the first via V0 extends vertically through the base layer 311.

A portion of the first via V0 may be filled with a filling metal 304. In an embodiment, the filling metal 304 may include Mo, W, Ru, Co, Cu or MoW. In an embodiment, the filling metal 304 may be formed through a single damascene process.

In an embodiment, the first wiring structure 314_1/314_2 may include a fifth metal layer 314_1 and a sixth metal layer 314_2 which are sequentially stacked. In an embodiment, each of the fifth metal layer 314_1 and the sixth metal layer 314_2 may include an MoW alloy. For example, in an embodiment, the composition of the MoW alloy may be in a range of about 25 to about 75 at % for Mo.

The fifth metal layer 314_1 may be disposed on the first via V0 and the base layer 311. Another portion of the first via V0 may be filled with the fifth metal layer 314_1. The fifth metal layer 314_1 may be disposed on a filling metal 304, and may be connected to the filling metal 304.

In an embodiment, the fifth metal layer 314_1 may be formed through the same process as those of the above-described first metal layer 324 and the above-described third metal layer 334, and the sixth metal layer 314_2 may be formed through the same process as those of the above-described second metal layer 325 and the above-described fourth metal layer 335. In an embodiment, the resistivity of the fifth metal layer 314_1 and the resistivity of the sixth metal layer 314_2 may be different.

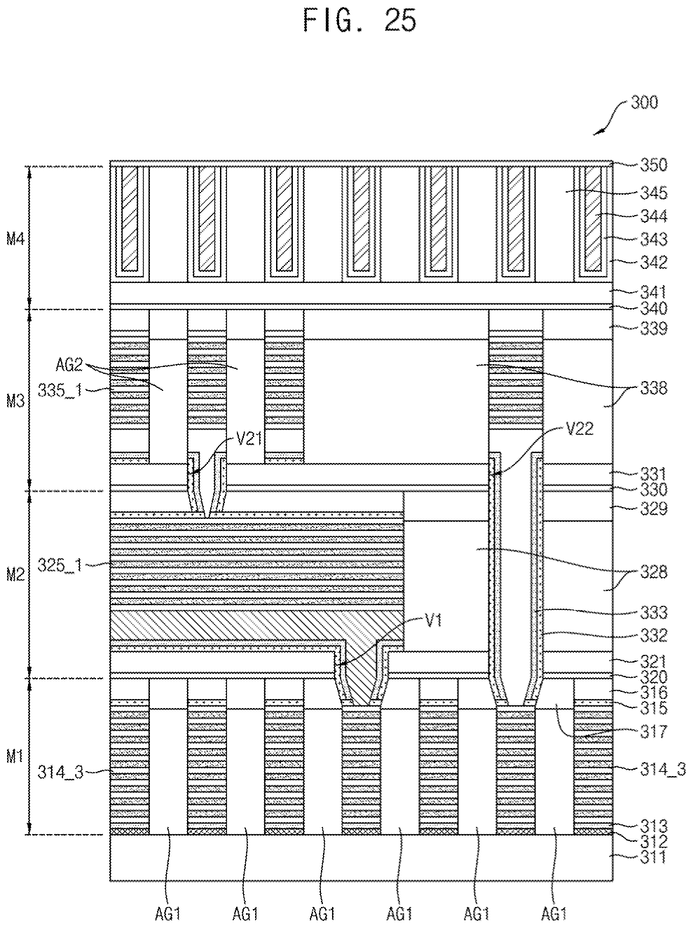

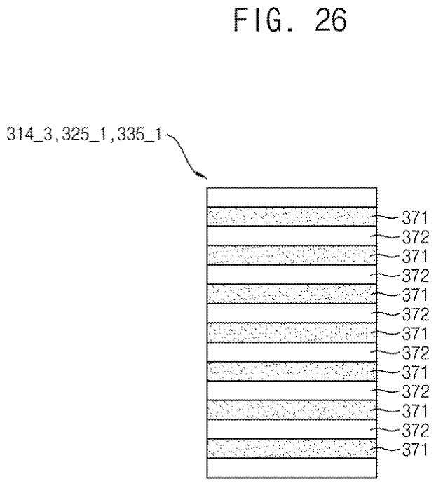

FIG. 25 is a cross-sectional view showing a portion of a BEOL structure according to an embodiment of the present inventive concept. FIG. 26 is a view showing a super-lattice structure of FIG. 25.

Referring to FIGS. 25 and 26, a BEOL structure 300_3 according to the embodiment differs from the BEOL structure 300 according to the embodiment of FIG. 2 in that a first wiring structure 314_3, a second metal layer 325_1 and a fourth metal layer 335_1 have different multilayer structures, respectively.

In an embodiment, each of the first wiring structure 314_3, the second metal layer 325_1 and the fourth metal layer 335_1 may have a super-lattice structure. The super-lattice structure may also be referred to as a “super-alloy structure”.

Each of the first wiring structure 314_3, the second metal layer 325_1 and the fourth metal layer 335_1 may have a structure in which a first metal film 371 and a second metal film 372 are alternately stacked (e.g., in the vertical direction). In an embodiment, each of the first metal film 371 and the second metal film 372 may have a thickness in a range of about 0.5 to about 10 Å. In accordance with embodiments, thicknesses of the first metal film 371 and the second metal film 372 may be different.

For example, the first metal film 371 may include Mo, and the second metal film 372 may include W. For example, the super-lattice structure applied to each of the first wiring structure 314_3, the second metal layer 325_1 and the fourth metal layer 335_1 may be a multilayer structure in the form of (W/Mo)×N or (Mo/W)×N.

When such a super-lattice structure is applied to the first wiring structure 314_3, the second metal layer 325_1 and the fourth metal layer 335_1, formation of beta-W may be suppressed during deposition of a W seed layer exhibiting high resistivity and, as such, it may be possible to secure predetermined resistivity. A uniform grain size and a uniform composition distribution may be secured during deposition. Accordingly, excellent corrosion resistance may be obtained.

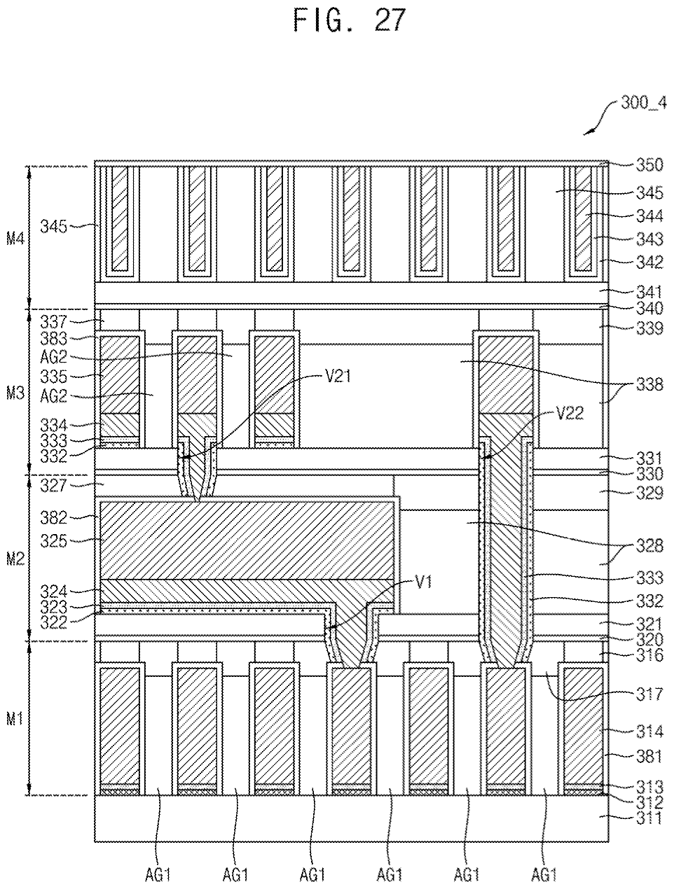

FIG. 27 is a cross-sectional view showing a portion of a BEOL structure according to an embodiment of the present inventive concept.

Referring to FIG. 27, a BEOL structure 300_4 according to an embodiment differs from the BEOL structure 300 according to the embodiment of FIG. 2 in that the BEOL structure 300_4 further includes encapsulation films 381, 382 and 383 disposed at outer surfaces of wiring structures 314, 324/325 and 334/335, respectively.

In an embodiment, the BEOL structure 300_4 may further include the encapsulation films 381, 382 and 383 surrounding upper and side surfaces of respective wiring structures 314, 324/325 and 334/335. For example, in an embodiment, the encapsulation films 381, 382 and 383 may include graphene. In accordance with embodiments, the encapsulation films 381, 382 and 383 may be selectively formed at the side surfaces of the wiring structures 314, 324/325 and 334/335, respectively.

In an embodiment, the encapsulation films 381, 382 and 383 may be formed at surfaces of the wiring structures 314, 324/325 and 334/335 through an in-situ deposition process, respectively.

The encapsulation films 381, 382 and 383 may include functions for preventing nitrification or oxidation of the wiring structures 314, 324/325 and 334/335, respectively. For example, the encapsulation films 381, 382 and 383 may be deposited through an in-situ deposition process immediately after formation of the wiring structures 314, 324/325 and 334/335 and, as such, surface oxidation of the wiring structures 314, 324/325 and 334/335 caused by exposure to the atmosphere may be prevented. In addition, since graphene is composed only of C and H, it may be possible to prevent formation of oxide or nitride on a surface of each of the wiring structures 314, 324/325 and 334/335 when the encapsulation films 381, 382 and 383 are deposited on the surfaces of the wiring structures 314, 324/325 and 334/335, respectively. In accordance with embodiments, before deposition of the encapsulation films 381, 382 and 383, an H₂, H₂ plasma or H radical annealing process may be performed in a range of about 350 to about 750° C.

In an embodiment, the thickness of each of the encapsulation films 381, 382 and 383 may be in a range of about 1 to about 5 nm, or may be about 0.5 to about 3 nm, taking into consideration each pitch of the wiring structures 314, 324/325 and 334/335.

In accordance with an embodiment of the present inventive concept, a wiring structure applied to an integrated circuit chip may exhibit low resistivity, provide a short electron mean free path (ENFP) and achieve easy patterning while having a line width of 12 nm or less.

The wiring structure, which is applicable to an integrated circuit chip, may minimize influence of external damage while having a small line width.

While embodiments of the present inventive concept have been described with reference to the accompanying drawings, it should be understood by those skilled in the art that various modifications may be made without departing from the scope of the present inventive concept and without changing essential features thereof. Therefore, the above-described embodiments should be considered in a descriptive sense only and not for purposes of limitation.

What is claimed is:

1. An integrated circuit chip comprising:
a base layer;
a first wiring layer disposed on the base layer, the first wiring layer including a plurality of first wiring structures;
a second wiring layer disposed on the first wiring layer, the second wiring layer including a plurality of second wiring structures, each of the plurality of second wiring structures has a first metal layer and a second metal layer respectively having different resistivities; and
a third wiring layer disposed on the second wiring layer, the third wiring layer including a plurality of third wiring structures,
wherein each of the plurality of first wiring structures comprises Ru, Mo, W, or an alloy thereof,
wherein each of the plurality of second wiring structures comprises Ru, Mo, W, or an alloy thereof,
wherein each of the plurality of third wiring structures comprises a material different from a material of the plurality of first wiring structures.

2. The integrated circuit chip according to claim 1, wherein each of the plurality of first wiring structures, the first metal layer and the second metal layer comprises an MoW alloy.

3. The integrated circuit chip according to claim 2, wherein each of the plurality of third wiring structures comprises Cu, Ir, Rh or Co.

4. The integrated circuit chip according to claim 1, wherein the first metal layer and the second metal layer are formed through different deposition processes, respectively.

5. The integrated circuit chip according to claim 1, wherein the plurality of first wiring structures and the plurality of third wiring structures are formed through different deposition processes, respectively.

6. The integrated circuit chip according to claim 1, further comprising:
a first seed layer and a first adhesive layer disposed under the plurality of first wiring structures, and a second seed layer and a second adhesive layer disposed under the plurality of second wiring structures,
wherein each of the first and second seed layers comprises W, Mo, or an alloy thereof and has a thickness in a range of about 0.5 to about 5 nm,
wherein each the first and second adhesive layers comprises MoN or WN.

7. The integrated circuit chip according to claim 6, wherein each of the first and second seed layers is disposed directly under corresponding ones of the plurality of first wiring structures and the plurality of second wiring structures.

8. The integrated circuit chip according to claim 1, wherein:
each of the plurality of first wiring structures and the second wiring layer has a structure in which a first metal film and a second metal film are alternately stacked; and
a thickness of the first metal film and a thickness of the second metal film are in a range of about 0.5 to about 10 Å.

9. The integrated circuit chip according to claim 8, wherein:
the thickness of the first metal film and the thickness of the second metal film are different from each other;
the first metal film comprises Mo; and
the second metal film comprises W.

10. The integrated circuit chip according to claim 1, wherein:
the first wiring layer comprises a first air gap formed between the plurality of first wiring structures; and
the second wiring layer comprises a second air gap formed between the plurality of second wiring structures.

11. The integrated circuit chip according to claim 10, wherein the third wiring layer does not include an air gap.

12. The integrated circuit chip according to claim 1, wherein the first metal layer is connected to at least one of the plurality of first wiring structures through a via.

13. The integrated circuit chip according to claim 1, further comprising:
a first capping pattern disposed on the first wiring structures, and a second capping pattern disposed on the second wiring structures,
wherein each of the first and second capping patterns comprises at least one compound selected from SiO₂, Al₂O₃, TiOx, TaOx, HfOx, ZrOx, MgO, SiN, TiN or TaN.

14. The integrated circuit chip according to claim 1, wherein a width of each of the plurality of first wiring structures and a width of each of the plurality of second wiring structures is in a range of about 12 nm or less.

15. An integrated circuit chip comprising:
a first wiring layer comprising a plurality of first MoW alloy wiring structures, and a first encapsulation film surrounding each of the plurality of first MoW alloy wiring structures; and
a second wiring layer disposed on the first wiring layer, the second wiring layer comprising a plurality of second MoW alloy wiring structures, and a second encapsulation film surrounding each of the plurality of second MoW alloy wiring structures,
wherein a portion of the plurality of second MoW alloy wiring structures is connected to a portion of the plurality of first MoW alloy wiring structures,
wherein a width of each of the plurality of first MoW alloy wiring structures and a width of each of the plurality of second MoW alloy wiring structures are in a range of about 12 nm or less.

16. The integrated circuit chip according to claim 15, wherein the first encapsulation film and the second encapsulation film comprise graphene.

17. The integrated circuit chip according to claim 15, wherein:
each of the plurality of first MoW alloy wiring structures has a single-layer structure; and
each of the plurality of second MoW alloy wiring structures has a multilayer structure including a first metal layer and a second metal layer respectively having different resistivities.

18. The integrated circuit chip according to claim 17, wherein the plurality of first MoW alloy wiring structures and the second metal layer are formed through a physical deposition process.

19. The integrated circuit chip according to claim 18, wherein:
the first metal layer is connected to a portion of the plurality of first MoW alloy wiring structures through a via; and
the first metal layer is formed through an atomic layer deposition process or a chemical vapor deposition process.

20. An integrated circuit chip comprising:
a substrate having an active surface, and a back surface opposite to the active surface;
a front-end-of-line (FEOL) structure disposed on the active surface of the substrate, the FEOL structure including a transistor;
a back-end-of-line (BEOL) structure disposed on the FEOL structure; and
a plurality of bumps disposed on the BEOL structure,
wherein the BEOL structure comprises:
a first wiring layer comprising a plurality of first MoW alloy wiring structures, and
a second wiring layer disposed on the first wiring layer, the second wiring layer comprising a plurality of second MoW alloy wiring structures, and
a third wiring layer disposed on the second wiring layer, the third wiring layer comprising a plurality of third wiring structures each comprising a core metal, a liner film surrounding the core metal and a barrier film surrounding the liner film,
wherein a portion of the plurality of second MoW alloy wiring structures is connected to a portion of the plurality of first MoW alloy wiring structures,
wherein a portion of the plurality of first MoW alloy wiring structures is electrically connected to the transistor.
